(19) United States
(12) Patent Application Publication
(10) Pub. No.: US 2023/0178423 A1
(43) Pub. Date: Jun. 8, 2023

(54) TOP VIA WITH PROTECTIVE LINER

(71) Applicant: INTERNATIONAL BUSINESS MACHINES CORPORATION, ARMONK, NY (US)

(72) Inventors: Tao Li, Slingerlands, NY (US); Ruilong Xie, Niskayuna, NY (US); Tsung-Sheng Kang, Ballston Lake, NY (US); Chih-Chao Yang, Glenmont, NY (US)

(21) Appl. No.: 17/457,444

(22) Filed: Dec. 3, 2021

(51) Int. Cl. H01L 21/768; H01L 23/522; H01L 23/532

(52) U.S. Cl. CPC H01L 21/7682; H01L 23/5226; H01L 23/53238; H01L 23/53266; H01L 21/76843

(57) ABSTRACT

An interconnect structure and a method of forming the interconnect structure are provided. The interconnect structure includes one or more metal lines and one or more top vias in direct contact with a top surface of the one or more metal lines. The interconnect structure also includes a liner formed on sidewalls of the one or more top vias and top portions of the one or more metal lines.

### BACKGROUND

This disclosure relates generally to integrated circuit fabrication and, more particularly, to interconnect devices.

Back end of line (BEOL) is the portion of integrated circuit fabrication where the individual devices (transistors, capacitors, resisters, etc.) get interconnected with wiring on the wafer, the metallization layer. BEOL generally begins when the first layer of metal is deposited on the wafer. BEOL includes contacts, insulating layers (dielectrics), metal levels, and bonding sites for chip-to-package connections. A via is an electrical connection between layers in a physical electronic circuit that goes through the plane of one or more adjacent layers. In integrated circuit design, a via is a small opening in an insulating oxide layer that allows a conductive connection between different layers.

### SUMMARY

Embodiments relate to an interconnect structure and a method of forming the interconnect structure. According to one aspect, an interconnect structure is provided. The interconnect structure may include one or more metal lines and one or more top vias in direct contact with a top surface of the one or more metal lines. The interconnect structure also includes a liner formed on sidewalls of the one or more top vias and top portions of the one or more metal lines.

According to another aspect, an interconnect structure is provided. The interconnect structure may include one or more metal lines in direct contact with a top surface of one or more devices and one or more top vias in direct contact with a top surface of the one or more metal lines. The interconnect structure may include a liner formed on sidewalls of the one or more top vias and top surfaces of the one or more metal lines. The interconnect structure may also include an ultra-low-k dielectric material in direct contact with the liner, sidewalls of the one or more metal lines, and a top surface of the one or more devices.

According to another aspect, a method of forming an interconnect structure is provided. The method may include forming one or more metal lines and forming sacrificial material between the one or more metal lines. One or more top vias may be defined based on recessing at least a portion of the sacrificial material and one or more of the one or more metal lines. A liner may be formed on sidewalls of the one or more defined top vias and a top surface of the one or more metal lines.

### BRIEF DESCRIPTION OF THE DRAWINGS

These and other objects, features and advantages will become apparent from the following detailed description of illustrative embodiments, which is to be read in connection with the accompanying drawings. The various features of the drawings are not to scale as the illustrations are for clarity in facilitating the understanding of one skilled in the art in conjunction with the detailed description. In the drawings:

FIGS. 1-5 illustrate the steps of a method of forming an interconnect structure, according to at least one embodiment;

FIG. 1 depicts a cross-sectional view of a semiconductor structure after an initial set of processing operations, according to at least one embodiment;

FIG. 2 depicts a cross-sectional view of a process an etch process used in top via formation, according to at least one embodiment;

FIG. 3 depicts a cross-sectional view of a process of formation of a liner on exposed portions of metal lines, according to at least one embodiment;

FIG. 4 depicts a cross-sectional view of a process of removal of a liner and an interlayer dielectric layer, according to at least one embodiment;

FIG. 5 depicts a cross-sectional view of a process of formation of an ultra-low-k layer, according to at least one embodiment; and

FIG. 6 depicts an operational flowchart illustrating the steps of fabricating an interconnect device, according to at least one embodiment.

The drawings are not necessarily to scale. The drawings are merely schematic representations, not intended to portray specific parameters. The drawings are intended to depict only typical embodiments. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. Those structures and methods may, however, be embodied in many different forms and should not be construed as limited to the exemplary embodiments set forth herein. Rather, these exemplary embodiments are provided so that this disclosure will be thorough and complete and will fully convey the scope to those skilled in the art. In the description, details of well-known features and techniques may be omitted to avoid unnecessarily obscuring the presented embodiments.

Embodiments of this disclosure relate generally to integrated circuit fabrication and, more particularly, to interconnect devices. Back end of line (BEOL) is the portion of integrated circuit fabrication where the individual devices (transistors, capacitors, resisters, etc.) get interconnected with wiring on the wafer, the metallization layer. BEOL generally begins when the first layer of metal is deposited on the wafer. BEOL includes contacts, insulating layers (dielectrics), metal levels, and bonding sites for chip-to-package connections. A via is an electrical connection between layers in a physical electronic circuit that goes through the plane of one or more adjacent layers. In integrated circuit design, a via is a small opening in an insulating oxide layer that allows a conductive connection between different layers.

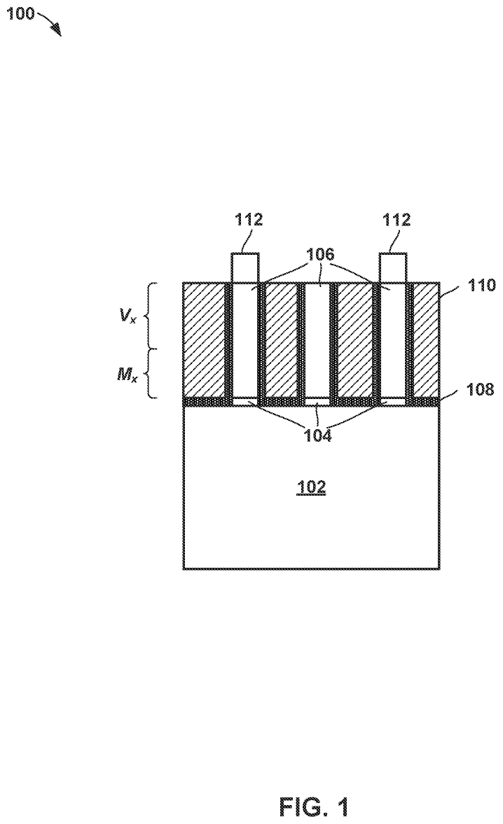

During top via formation using tall metal lines, a dielectric layer may be used as a scaffold to support the metal lines during processing. However, when this scaffold is removed, the etch process to remove the scaffold may cause degradation and damage to the tall metal lines. In particular, the top via portion of the tall metal lines may undergo significant over-etching as a result of poor selectivity to the etchant. It may be advantageous, therefore, to protect the top via prior to removal of the interlayer dielectric layer to prevent damage to the top via. This may be done by growing, prior to removal of the liner, a selective metal or dielectric liner on the exposed portions of top via that may withstand the etch process. One way to fabricate an integrated circuit with selective metal or dielectric liner is described in detail below by referring to the accompanying drawings FIGS. 1-5.

It is understood in advance that although example embodiments of this disclosure are described in connection with a particular transistor architecture, embodiments of this disclosure are not limited to the particular device architectures or materials described in this specification. Rather, embodiments of this disclosure are capable of being implemented in conjunction with any other type of device architecture or materials now known or later developed.

For the sake of brevity, conventional techniques related to semiconductor device and integrated circuit fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based integrated circuits are well known and so, in the interest of brevity, many conventional steps will only be mentioned briefly herein or will be omitted entirely without providing the well-known process details.

Detailed embodiments of the claimed structures and methods are disclosed herein; however, it is to be understood that the disclosed embodiments are merely illustrative of the claimed structures and methods that may be embodied in various forms. In addition, each of the examples given in connection with the various embodiments are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the methods and structures of the present disclosure. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “an example embodiment,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “overlaying,” “atop,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

Turning now to an overview of technologies that are more specifically relevant to aspects of this disclosure, integrated circuits are fabricated in a series of stages, including a front-end-of-line (FEOL) stage, a middle-of-line (MOL) stage, and a BEOL stage. The process flows for fabricating modern integrated circuits are often identified based on whether the process flows fall in the FEOL stage, the MOL stage, or the BEOL stage. Generally, the FEOL stage is where device elements (e.g., transistors, capacitors, resistors) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the integrated circuit. Most integrated circuits need more than one layer of wires to form all the necessary connections, and as many as 5-12 layers are added in the BEOL process. The various BEOL layers are interconnected by vias that couple from one layer to another.

Insulating dielectric materials are used throughout the layers of an integrated circuit to perform a variety of functions, including stabilizing the integrated circuit structure and providing electrical isolation of the integrated circuit elements. For example, the metal interconnecting wires in the BEOL region of the integrated circuit are isolated by dielectric layers to prevent the wires from creating a short circuit with other metal layers.

As used herein, a “top via” refers to the “Vₓ” layer via which electrically couples a line below (an “Mₓ” layer) and may also electrically couple to a line above (an “Mₓ₊₁” layer). Embodiments of this disclosure form an alternate metal top via (e.g., Co, Ru) on the metal line below. There may be no barrier metal between the top via and the line metal below. For ease of depiction, the metal lines and vias are illustrated herein as having a constant width. However, it may be appreciated that both the metal line and via may have a positive tapered angle such that the width narrows in an upward direction towards the top of the component (e.g., the width top of the via may be more narrow than the width at the bottom of the via).

Referring now to FIGS. 1-5, exemplary process steps of forming an interconnect device in accordance with one or more embodiments is shown and will now be described in greater detail below. It should be noted that FIGS. 1-5 all represent a cross section view of an integrated circuit structure 100 depicting the fabrication of an interconnect device.

Referring now to FIG. 1, a fabrication step of the integrated circuit structure 100, in accordance with one or more embodiments, is depicted. FIG. 1 depicts a cross-sectional view of a semiconductor structure after an initial set of processing operations. The integrated circuit structure 100 may include, among other things, an underneath device 102, a liner 104, metal lines 106, a liner 108, a sacrificial dielectric layer 110, and a hardmask 112.

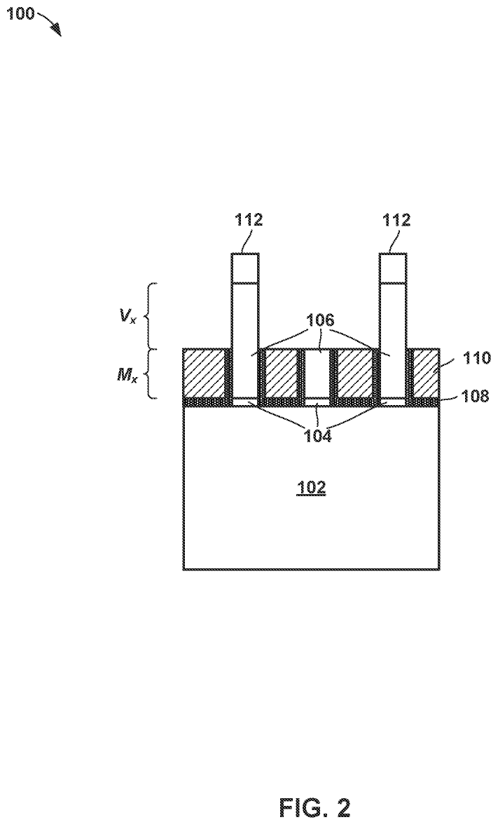

The underneath device 102 may comprise either FEOL devices (e.g., transistors, capacitors, resisters), MOL, or additional BEOL metallization layers. The particular composition of the underneath device 102 may vary based on the type of device desired. For ease of description, the underneath device 102 is depicted as a single box in FIG. 2 for illustrative purposes. It may be appreciated that the area shown as the underneath device 102 may be substantially any combination of devices.

The liner 104 is formed on the underneath device 102 by physical vapor deposition (e.g., sputtering), chemical vapor deposition, or atomic layer deposition to form a thickness of about 0.5 nm to about 3 nm, although other thicknesses are within the contemplated scope of this disclosure. The liner 104 may be a conductor such as titanium nitride (TiN), titanium aluminum carbide (TiAlC), titanium carbide (TiC), or tantalum nitride (TaN). In some embodiments, the liner 104 may be comprised of other conductive materials such as aluminum (Al), copper (Cu), nickel (Ni), cobalt (Co), ruthenium (Ru), or combinations thereof.

The metal lines 106 may be deposited as a metal layer that is subsequently formed into the metal lines 106 as described below. The metal lines 106 may be formed from any type of conductive metal. For example, the metal lines 106 may be composed of Ru, Cu, Co, molybdenum (Mo), tungsten (W), Al, or rhodium (Rh). The metal layer may be deposited on the liner 104 using, for example, chemical vapor deposition, plasma enhanced chemical vapor deposition, physical vapor deposition, or other deposition processes. The metal layer may be deposited to form a thickness of 20 to 200 nm, although other thicknesses are within the contemplated scope of this disclosure. The metal lines 106 may include a top via layer Vₓ and an underlying metal layer Mₓ. The metal lines 106 may be formed using subtractive patterning techniques.

The liner 108 may be deposited on exposed top and sidewall surfaces of the integrated circuit structure 100. More particularly, the liner 108 may be deposited on exposed surfaces of the underneath device 102, the liner 104, and the metal lines 106. The liner 108 may be produced by forming a layer (e.g., silicon nitride (SiN)), using an in situ radical assisted deposition (iRAD) process, which creates a very conformal layer and a dense film for the liner 108. Techniques other than iRAD may be used to create the liner 108, such as low-pressure chemical vapor deposition.

The sacrificial dielectric layer 110 may be a non-crystalline solid material such as silicon dioxide (SiO₂) undoped silicate glass (USG), fluorosilicate glass (FSG), borophosphosilicate glass (BPSG), a spin-on low-k dielectric layer, a chemical vapor deposition low-k dielectric layer or any combination thereof. The term “low-k” as used throughout the present disclosure denotes a dielectric material that has a dielectric constant of less than silicon dioxide. In another embodiment, a self-planarizing material such as a spin-on glass (SoG) or a spin-on low-k dielectric material can be used as the sacrificial dielectric layer 110. The use of a self-planarizing dielectric material as the sacrificial dielectric layer 110 may avoid the need to perform a subsequent planarizing step.

In some embodiments, the sacrificial dielectric layer 110 can be formed on exposed surfaces of liner 108 utilizing a deposition process including, for example, chemical vapor deposition, plasma enhanced chemical vapor deposition, evaporation, or spin-on coating. In some embodiments, particularly when non-self-planarizing dielectric materials are used as the sacrificial dielectric layer 110, a planarization process or an etch back process follows the deposition of the dielectric material that provides the sacrificial dielectric layer 110. The liner 108 and the sacrificial dielectric layer 110 may be considered as sacrificial material for use in defining top vias from the metal lines 106.

The hardmask 112 may be an organic planarization layer or any other type of hardmask layer. For example, the hardmask 112 may be composed of metal or a dielectric material such as, for example, a low-k dielectric, a nitride, silicon nitride, silicon oxide, SiON, SiC, SiOCN, or SiBCN. In some embodiments of this disclosure, the hardmask 112 is a silicon nitride or silicon oxide hard mask. In some embodiments of this disclosure, the hardmask 112 is formed to a thickness of about 40 nm to about 600 nm, for example 60 nm, although other thicknesses are within the contemplated scope of this disclosure. The hardmask 112 may be deposited using, for example, any suitable process, such as chemical vapor deposition, plasma enhanced chemical vapor deposition, ultrahigh vacuum chemical vapor deposition, rapid thermal chemical vapor deposition, metalorganic chemical vapor deposition, low-pressure chemical vapor deposition, limited reaction processing chemical vapor deposition, atomic layer deposition, flowable chemical vapor deposition, spin-on dielectrics, physical vapor deposition, molecular beam epitaxy, chemical solution deposition, spin-on dielectrics, or other like process.

Referring now to FIG. 2, etching of the metal lines 106, the liner 108, and the sacrificial dielectric layer 110 is depicted, according to one or more embodiments. The metal lines 106 may be recessed to define one or more top vias on the integrated circuit structure. Where top vias are desired on the integrated circuit structure 100, the Vₓ layer of the metal lines 106 corresponding to desired top via locations are covered by the hardmask 112 and are not recessed. Conversely, where top vias are not desired, the Vₓ layer of the metal lines 106 corresponding to such locations may be recessed. Such portions of the metal lines 106 areas are not covered by the hardmask 112 and may undergo an etch process. The etch process may include reactive ion etching, laser ablation, or any etch process which can be used to selectively remove a portion of material.

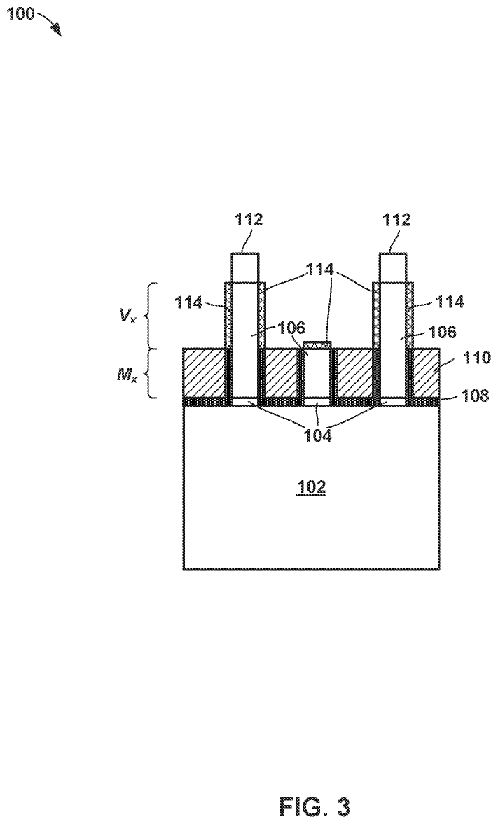

Referring now to FIG. 3, formation of a protective liner on the exposed portions of the metal lines 106 is depicted, according to one or more embodiments. According to one or more embodiments, a liner 114 is formed on exposed sidewalls of the Vₓ layer of the metal lines 106 or on the top surface of an Mₓ layer of the metal lines 106. Because the sidewalls of the Mₓ layer of the metal lines 106 remain covered by the sacrificial dielectric layer 110, the liner 114 cannot form on the sidewalls of the Mₓ layer. The liner 114 may be a metal, such as titanium or tungsten. The liner 114 may be a metal liner having a high etch selectivity value. The liner 114 may be formed by selective metal growth on the metal lines 106. The liner 114 may alternatively be a dielectric material formed on the metal lines 106 by a deposition process including, for example, chemical vapor deposition, plasma enhanced chemical vapor deposition, evaporation.

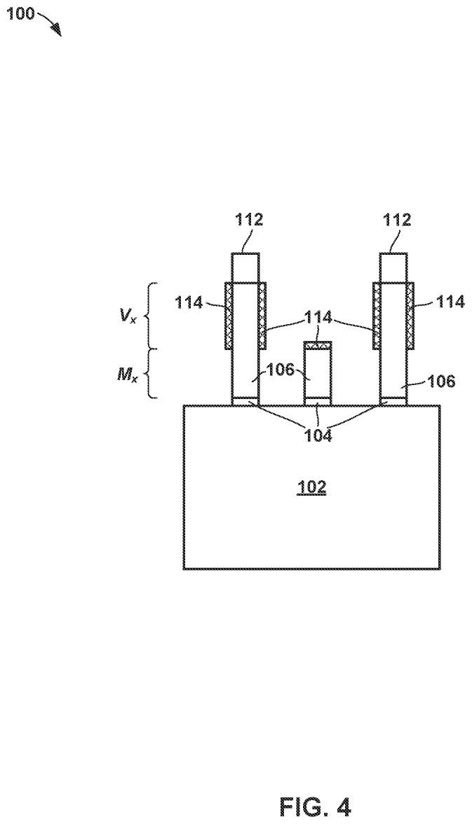

Referring now to FIG. 4, removal of the liner 108 and the sacrificial dielectric layer 110 is depicted, according to one or more embodiments. The liner 114 may protect the top via portion of the metal lines 106 from being damaged during removal of the liner 108 and the sacrificial dielectric layer 110 at the Mₓ layer. The sacrificial dielectric layer 110 may first be removed through a known etching process. In one or more embodiments, the liner 114 may act as a sacrificial layer that may be thinned during the etch process based on the etch selectivity of the material used for the liner 114. In general, during such an etch process, the hardmask 112 and the liner 108 may protect the metal lines 106 during the removal of the sacrificial dielectric layer 110. The liner 108 may subsequently be removed by an additional etching process.

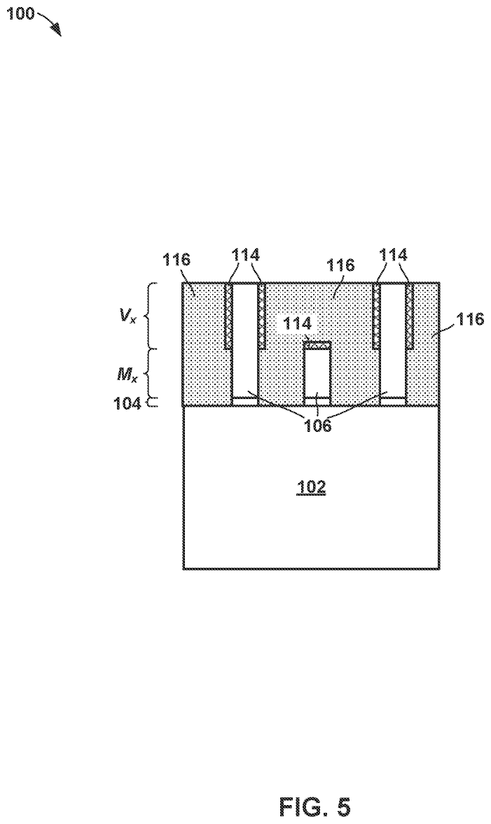

Referring now to FIG. 5, formation of a dielectric layer 116 is depicted, according to one or more embodiments. The dielectric layer 116 is generally a layer of ultra-low-k dielectric material. A low-k material is a material with a small relative dielectric constant (k) relative to SiO₂. Low-k materials include, for example, SiCOH, fluorine-doped SiO₂, organosilicate glass (OSG), porous SiO₂, porous organosilicate glass, spin-on organic polymeric dielectrics, and spin-on silicon based polymeric dielectrics. In some embodiments, the dielectric layer 116 is spin-on-glass. Spin-on-glass is an interlayer dielectric material applied in liquid form to fill narrow gaps in the sub-dielectric surface. In some embodiments, the dielectric layer 116 is deposited using flowable chemical vapor deposition or spin-on dielectric methods. The dielectric layer 116 may be deposited above the desired height. In embodiments where the dielectric layer 116 is deposited above the desired height, a subsequent polishing process, such as chemical-mechanical planarization, may be utilized to reduce the height of the dielectric layer 116.

As previously described, during top via formation using tall metal lines, such as the metal lines 106, a dielectric layer (e.g., the sacrificial dielectric layer 110) may be used as a scaffold to support the metal lines 106 during processing. However, when the sacrificial dielectric layer 110 is removed, the etch process used to remove the sacrificial dielectric layer 110 may cause degradation and damage to the top, Vₓ layer of the metal lines 106. In particular, the top via portion (i.e., the Vₓ layer) of the metal lines 106 may undergo significant over-etching as a result of poor selectivity of the material of the metal lines 106 to the etchant. Thus, the liner 114 disclosed herein is grown or deposited on the Vₓ layer of the metal lines 106 prior to removal of the sacrificial dielectric layer 110 in order to prevent damage to the top via portion of the metal lines 106.

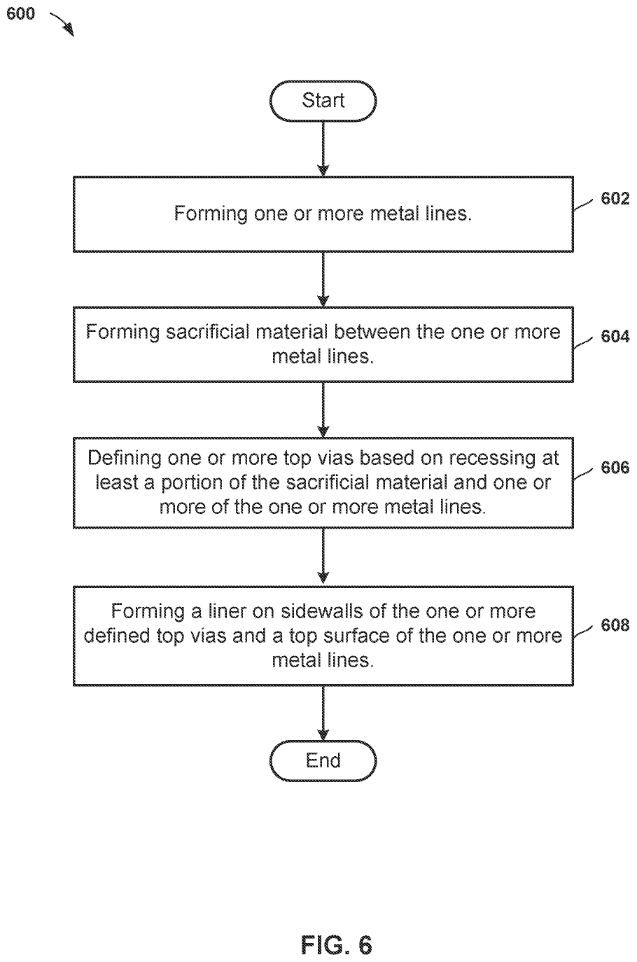

Referring now to FIG. 6, an operational flowchart illustrating the steps of a method 600 for forming an interconnect structure is depicted.

At 602, the method 600 may include forming one or more metal lines.

At 604, the method 600 may include forming sacrificial material between the one or more metal lines.

At 606, the method 600 may include defining one or more top vias based on recessing at least a portion of the sacrificial material and one or more of the one or more metal lines.

At 608, the method 600 may include forming a liner on sidewalls of the one or more defined top vias and a top surface of the one or more metal lines.

It may be appreciated that FIG. 6 provides only an illustration of one implementation and does not imply any limitations with regard to how different embodiments may be implemented. Many modifications may be made based on design and implementation requirements.

The resulting structure described above is a BEOL metal line and top via interconnect structure that includes metal lines and top vias with a selective metal or dielectric liner. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of this disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. An interconnect structure comprising:
one or more metal lines;
one or more top vias in direct contact with a top surface of the one or more metal lines; and
a liner formed on sidewalls of the one or more top vias and top portions of the one or more metal lines.

2. The interconnect structure of claim 1, wherein the liner is not in contact with the sidewalls of the one or more metal lines.

3. The interconnect structure of claim 1, wherein the metal line and the top via are composed of a material selected from the group consisting of: ruthenium, cobalt, molybdenum, tungsten, aluminum, and rhodium.

4. The interconnect structure of claim 1, wherein the liner comprises a material selected from the group consisting of: titanium, tungsten, and a dielectric material.

5. The interconnect structure of claim 1, further comprising:
an ultra-low-k dielectric material in direct contact with the liner and sidewalls of the one or more metal lines.

6. The interconnect structure of claim 5, further comprising one or more air gaps in the ultra-low-k dielectric material positioned between the one or more metal lines.

7. An interconnect structure comprising:
one or more metal lines in direct contact with a top surface of one or more devices;
one or more top vias in direct contact with a top surface of the one or more metal lines;
a liner formed on sidewalls of the one or more top vias and top surfaces of the one or more metal lines; and
an ultra-low-k dielectric material in direct contact with the liner, sidewalls of the one or more metal lines, and the top surface of the one or more devices.

8. The interconnect structure of claim 7, wherein the liner is not in contact with the sidewalls of the one or more metal lines.

9. The interconnect structure of claim 7, wherein the metal line and the top via are composed of a material selected from the group consisting of: ruthenium, cobalt, molybdenum, tungsten, aluminum, and rhodium.

10. The interconnect structure of claim 7, wherein the liner is composed of a material selected from the group consisting of: titanium, tungsten, and a dielectric material.

11. The interconnect structure of claim 5, further comprising one or more air gaps in the ultra-low-k dielectric material positioned between the one or more metal lines.

12. A method of forming an interconnect structure, comprising:
forming one or more metal lines;
forming sacrificial material between the one or more metal lines;
defining one or more top vias based on recessing at least a portion of the sacrificial material and one or more of the one or more metal lines; and
forming a liner on sidewalls of the one or more defined top vias and a top surface of the one or more metal lines.

13. The method of claim 12, wherein the sacrificial material comprises a dielectric layer.

14. The method of claim 12, further comprising removing the sacrificial material.

15. The method of claim 14, wherein the liner is not removed with the remaining sacrificial material.

16. The method of claim 12, wherein the liner is not in contact with the sidewalls of the one or more metal lines.

17. The method of claim 12, wherein the liner is formed by selective metal growth.

18. The method of claim 12, wherein the metal line and the top via are composed of a material selected from the group consisting of: ruthenium, cobalt, molybdenum, tungsten, aluminum, and rhodium.

19. The method of claim 12, wherein the liner is composed of a material selected from the group consisting of: titanium, tungsten, and a dielectric material.

20. The method of claim 12, further comprising:
forming a layer of an ultra-low-k dielectric material on the liner and the one or more metal lines.
